(19) United States
(12) Patent Application Publication
(10) Pub. No.: US 2003/0161110 A1
(43) Pub. Date: Aug. 28, 2003

(54) Electronic control module for a vehicle

(76) Inventors: Blagoj Spasevski, Doncaster (AU); Vincent Tarquinio, Bulleen (AU)

Correspondence Address: KENYON & KENYON, ONE BROADWAY, NEW YORK, NY, 10004, US

(21) Appl. No.: 10/275,055

(22) PCT Filed: Apr. 18, 2001
(86) PCT No.: PCT/DE01/01491

(30) Foreign Application Priority Data
May 4, 2000 (AU) PQ7294

(51) Int. Cl. H05K 7/20

(52) U.S. Cl. 361/715

(57) ABSTRACT

The present invention is directed to an electric actuator module (2) including a printed circuit board (PCB) (6) provided with at least one electronic component (12, 15) and at least one heat-dissipating means (14, 20) for the at least one electronic component; and a housing (4, 10) including a component (10) that is thermally connected to the heat-dissipating means (14); the one thermally conductive seal (8) for the housing (4, 10) including that the seal (8) is thermally connected to the heat-dissipating means (14, 20) and the component (10).

The present invention is directed to an electronic control module for a vehicle.

In the manufacture of vehicle components, strictest attention is paid to cost savings since every penny saved in a component is, of course, very important in the mass production of vehicles. One of the problems arising in control modules for vehicle electronics is that, in addition to reducing the manufacturing cost, there is the additional requirement that these parts be very robust so as to be able to withstand the most varied environmental conditions, including great temperature fluctuations and different impact and vibration levels. These modules must be adequately sealed and their electrical components protected against a large number of operating conditions given different environments. It is endeavored here to overcome the above difficulties and to provide at least a useful alternative to the electronic control-module configurations as they currently exist in the related art.

The electronic control module according to the present invention includes: a printed circuit board (PCB) provided with at least one electronic component and at least one heat-dissipating means for the at least one electronic component; and a housing with a component that is thermally connected to the heat-dissipation means; characterized in that it includes a thermally conductive seal for the housing, the seal being thermally connected to the heat-dissipation means and the component.

Preferably, the seal is made of a silicon- or aluminum oxide-based material.

The seal is preferably connected only to parts of the PCB that require cooling.

Preferably, the heat-dissipating means includes elements such as heat sinks, conductive paths and/or contact areas.

The seal may be appropriately cut out or contoured so as to avoid components or parts of the PCB that do not require cooling. The respective component may be a cover plate or a base plate of the housing made of metal, and the remaining part of the housing may be made of a plastic material.

Preferred embodiments of the present invention are described hereinafter merely by way of example, with reference to the enclosed drawings:

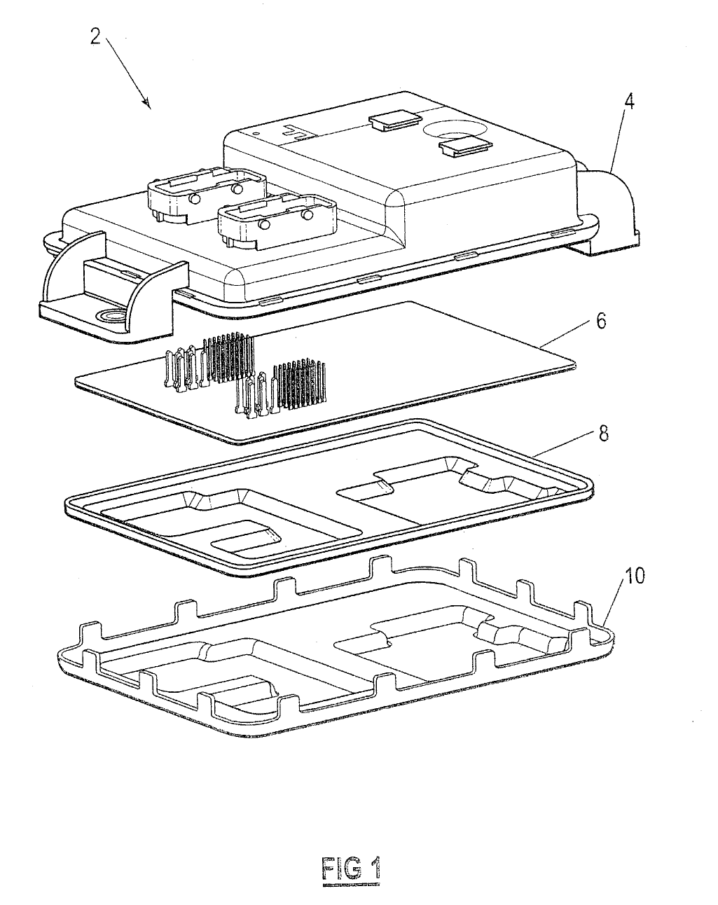

FIG. 1 is a pulled-apart perspective representation of a preferred implementation of an electronic control module.

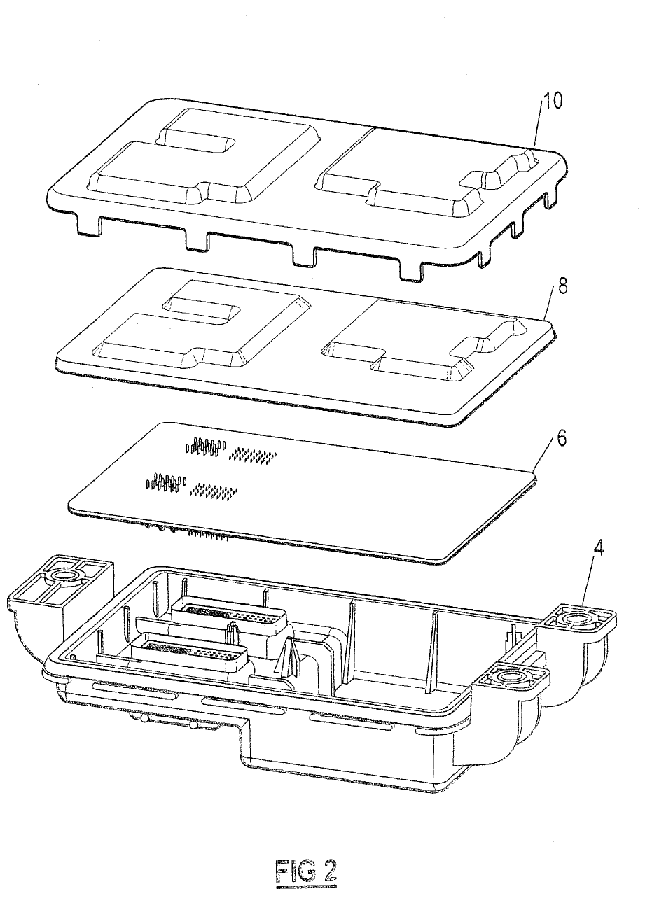

FIG. 2 is a second pulled-apart perspective representation of the electronic control module.

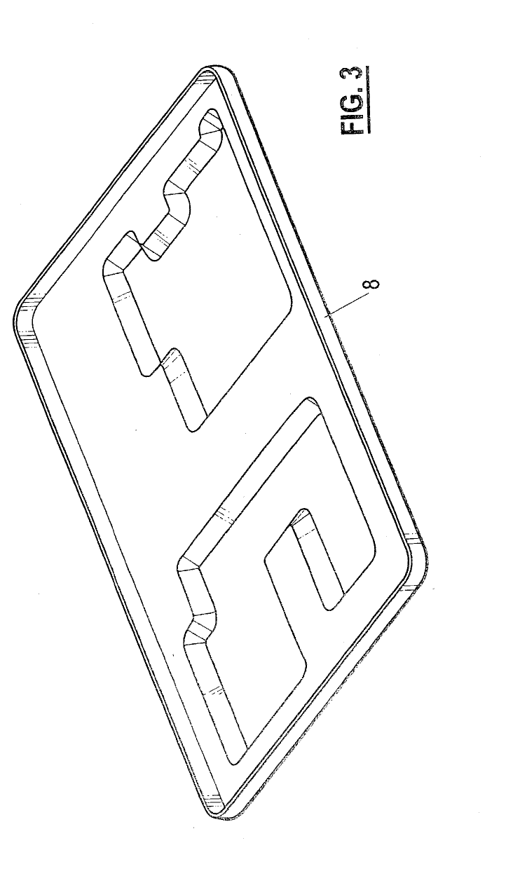

FIG. 3 is a perspective view of a thermal damping element of an electronic control module.

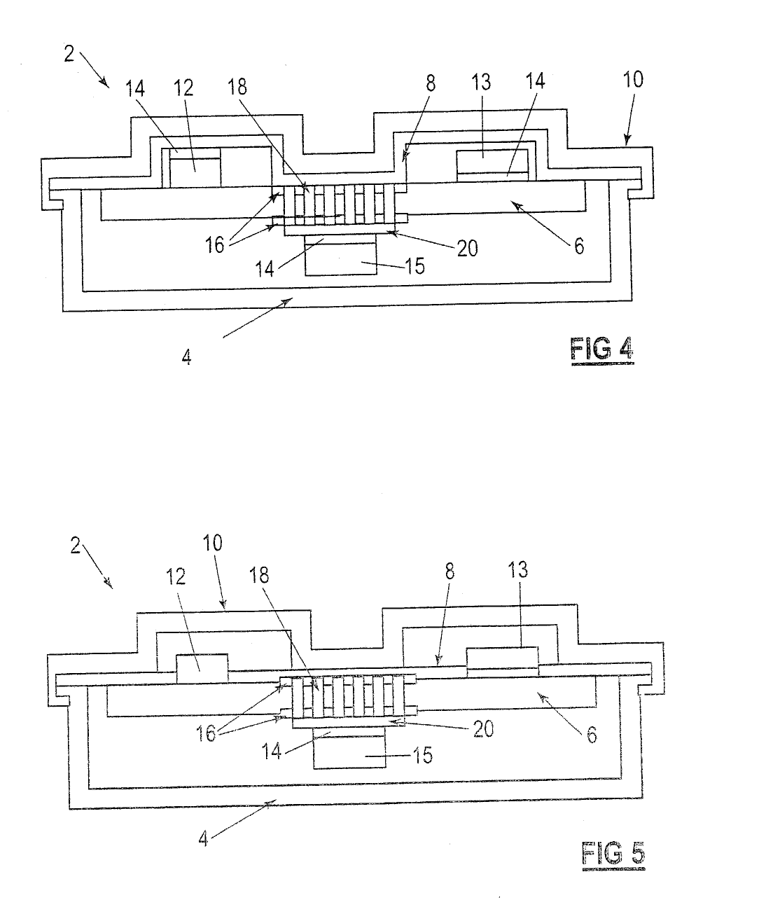

FIG. 4 is a cross-section of the electronic control module.

FIG. 5 is a cross-section of a further preferred implementation of the electronic control module.

An electronic control module 2, as shown in the figures, includes a plastic housing 4, a printed circuit board (PCB) 6 having printing on both sides, a metal cover plate 10 and a thermal damping element 8. Damping element 8 is a thermally conductive, electrically insulating damping element based on silicon. The damping element is used as an interface material between PCB 6 and cover plate 10 and, at the same time, provides low-value thermal resistance with respect to heat flow due to Joulean heat loss by components of PCB 6. Damping element 8 is used as a seal between housing 4 and cover plate 10. Moreover, damping element 8 provides the following:

(i) a low-value heat-resistance connection between the thermal conduction components of the PCB and cover plate 10;

(ii) an electric separation of the electronic components of the PCB and cover plate 10;

(iii) voltage discharge for the electronic components of the electronic control module during possibly occurring mechanical or thermal shocks; and

(iv) a seal between cover plate 10 and housing 4.

Damping element 8 is made of a material based on silicon and preferably contains silicon and aluminum oxide.

For the embodiments shown in FIGS. 1 through 4, damping element 8 is shaped such that it corresponds to the shape of cover plate 10 and rests flush against it. Damping element 8 is in direct contact with PCB 6 and, in particular, is in contact with components of PCB 6 that are provided to dissipate heat. For instance, PCB 6 includes semiconductor-chip components 12, 13 and 15 with heat-dissipating elements 14 attached thereto, such as heat sinks. For those of components 12 and 15 that require cooling, damping element 8 must be connected to elements 14 whereas, for those components 13 that do not require cooling, damping element 8 may be shaped such that it avoids the respective components and does not touch them. In addition, or alternatively, it is also possible to utilize heat-dissipating elements that are connected to conductive paths or contacts of the PCB and which receive heat flow from these and are separated from the components.

Printed circuit board 6 includes tin-coated copper-(Cu) damping elements 16 at opposite sides of PCB 6, which are connected by tin-coated thermal through-lines or lines 18 through PCB 6. Heat sink 14 of an electric component 15 is then able to be connected to one of copper damping elements 16 by a large solder contact 20. Copper damping element 16 at the opposite side of PCB 6 is connected to thermal damping element 8, as shown in FIGS. 4 and 5. This configuration offers a considerable improvement in the heat dissipation from component 15 connected to solder contact 20. In particular, the thermal through-lines 18 markedly improve the heat flow from dissipating components 14 and 20 to thermal damping element 8.

For the embodiment according to FIG. 5, damping element 8, instead of corresponding to the shape of cover plate 10, is cut such that it extends around electrical components 12 and 13 and abuts against cover plate 10 on the side of PCB 6. Heat-dissipating elements 14 of components 13 that require cooling are connected to thermal damping element 8 or are adjacent thereto, whereas components 12 that do not require cooling are not connected to damping element 8.

One skilled in the art will be aware of numerous modifications, without these deviating from the core and the scope of the present invention, which is described with reference to the attached drawings.

What is claimed is:

1. An electronic control module (2) comprising: a printed circuit board (PCB) (6) provided with at least one electronic component (12, 15) and at least one heat-dissipating means (14, 20) for the at least one electronic component; and a housing (4, 10) including a component (10) which is thermally connected to the heat-dissipating means (14); characterized in that the electronic control module includes a thermally conductive seal (8) for the housing (4, 10), the seal (8) being thermally connected to the heat-dissipating means (14, 20) and the component (10).

2. The electronic control module (2) as recited in claim 1, the seal (8) being made of a material based on silicon and aluminum oxide.

3. The electronic control module as recited in claim 1, the seal (8) only being connected to components (12, 14, 15, 20) of the PCB that require cooling.

4. The electronic control module as recited in claim 1, the heat-dissipating means (14, 20) including elements such as heat sinks, conductive paths and/or contact areas.

5. The electronic control module as recited in claim 1, the seal (8) being cut out or contoured so as to avoid components or parts (13) of the PCB that do not require cooling.

6. The electronic control module as recited in claim 1, the component (10) being a cover plate or a base plate of the housing (4, 10) and being made of metal.

7. The electronic control module as recited in claim 6, the remaining part (4) of the housing (4, 10) being made of a plastic material.
